(19) United States
(12) Patent Application Publication
(10) Pub. No.: US 2012/0292663 A1
(43) Pub. Date: Nov. 22, 2012

(54) Structure and Method for Monolithically Fabrication Sb-Based E/D Mode MISFETs

(75) Inventors: Heng-Kuang LIN, Zhubei City (TW); Han-Chieh HO, Kaohsiung City (TW); Pei-Chin CHIU, Yanshui Township (TW); Jen-Inn CHYI, Pingzhen City (TW)

(73) Assignee: National Central University, Zhongli City (TW)

(21) Appl. No.: 13/110,938

(22) Filed: May 19, 2011

(51) Int. Cl. H01L 29/778

(52) U.S. Cl. 257/190; 257/E29.246

(57) ABSTRACT

The invention provides two Sb-based n- or p-channel layer structures as a template for MISFET and complementary MISFET development. Four types of MISFET devices and two types of complementary MISFET circuit devices can be developed based on the invented layer structures. Also, the layer structures can accommodate more than one complementary MISFETs and more than one single active MISFETs to be integrated on the same substrate monolithically.

### TECHNICAL FIELD

The present invention relates to Sb-based E/D-mode MISFETs, and more particularly to the methods for fabricating Sb-based complementary MISFETs monolithically.

### BACKGROUND OF THE RELATED ART

In integrated circuits, a large number of individual circuit devices, such as CMOS, NMOS or PMOS Field-Effect-Transistor, are all formed on a single chip. Typically, feature sizes of such integrated circuits may be continuously reduced by an introduction of a new circuit to improve the performance of speed and power dissipation. The performance of signal processing is enhanced effectively by an increase in switching speed, which can be carried out by a reduction in the dimension of the unit cell. The transient current of the CMOS Field-Effect-Transistor that is generated by a switch from a logic low to a logic high can be significantly reduced by a decrease in switching time period. With a reduction in the channel length of FET, it needs to reduce the thickness of a gate dielectric to gain full capacitive coupling between a gate electrode and a channel layer, thereby forming an appropriate control over conductive channels when a control voltage applies to the gate electrode. For a device in a high-density integrated circuit, it typically has a channel length of 0.18 μm or less and a gate dielectric thickness of 2˜5 nm or less.

Recently, there has been considerable interest in the potential of III-V FET materials for advanced logic applications. III-V high-speed, low-power complementary logic technology could enhance digital circuit functionality and sustain Moore's law for additional generations. When these technologies are utilized in mixed signal circuits, a significant reduction in power consumption could also be obtained. Hetero-structure field-effect transistors (HFETs) made of antimonide-based compound semiconductor materials have intrinsic performance advantages due to the attractive electron and hole transport properties, low ohmic contact resistances, and unique band-lineup design flexibility within this material system. These advantages can be particularly exploited in applications where high-speed operation and low-power consumption are essential. Sb-based hetero-structure devices have intrinsic high-speed and low-power consumption advantages that can provide the enabling technology needed for these applications, which include space-based communications, imaging, sensing, identification, high-data-rate transmission, micro-air-vehicles, wireless and other portable systems. The low dc power consumption of Sb-based HEMTs is also attractive for large-scale active-array space-based radar applications which are particularly power-constrained.

Based-on the above description, the present invention provides layer structure and methods for monolithically fabricating Sb-based complementary MISFETs.

### SUMMARY

One objective of the present invention is to provide Sb-based epitaxial layer and device structures for E/D mode MISFETs.

Another objective of the present invention is to provide Sb-based epitaxial layer structure for monolithically fabricating Sb-based complementary MISFETs on the same substrate.

In order to achieve the objectives, the present invention consists of Sb-based epitaxial layer structure for developing the Sb-based E/D mode MISFETs. The substrate is preferably a semi-insulating GaAs substrate, or other suitable substrates for epitaxial growth. The epitaxial structure comprises a buffer layer which material is a combination of Al(aluminum), Ga(gallium), In(indium) and Sb(antimony), and a channel layer, which is formed on the buffer layer and which material is a combination of In(indium), Ga(gallium) and Sb(antimony) or In(indium), As(arsenic) and Sb(antimony). An n- or p-modulation doping is optionally formed in the buffer layer and at a specified depth beneath the channel. In addition, the present invention provides four methods for fabricating Sb-based E/D mode MISFETs.

In order to achieve the objectives, the present invention also provides two methods for fabricating Sb-based complementary MISFETs monolithically. First, n- and p-channel E-mode MISFETs that are used for forming complementary MISFETs are fabricated using foregoing epitaxial layer structure, and have a common channel layer material and substrate; second, the n- and p-channel E-mode MISFETs that are used for forming complementary MISFETs are fabricated using a stacked epitaxial layer structure where one epitaxial layer structure is atop of another. The epitaxial layer structure can be any of the two foregoing epitaxial layer structures but has no modulation doping in the buffer layer. An etching stop layer exists between two layer structures and a doped layer is inserted in the buffer layer of the top epitaxial layer structure for forming a back gate of the top MISFET device. The channel layer materials in the two epitaxial structures are optional and can be either InAsSb or InGaSb. The n- and p-channel E-mode MISFETs that are used for forming complementary MISFETs do not have a common channel layer but are made on the same substrate.

The present invention further provides a method for monolithically integrating complementary MISFETs and single active MISFETs on a common substrate for IC applications. A stacked epitaxial layer structure that has one epitaxial layer structure atop of another is selected. The top and bottom epitaxial layer structure can be any of the foregoing two epitaxial layer structures where the buffer modulation doping is optional. An etching stop layer exists between two structures. A doped layer is inserted in the buffer layer of the top epitaxial structure for forming a back gate of the upper MISFET device. The channel layer materials in the two epitaxial structures are optional and can be either InAsSb or InGaSb. More than one sets of complementary MISFETs can be integrated on the same substrate and the complementary MISFETs can be fabricated using either top or bottom epitaxial structure or both; more than one single active MISFETs can be integrated on the same substrate and the single active MISFETs can be fabricated using top or bottom epitaxial layer structure.

### BRIEF DESCRIPTION OF THE DRAWINGS

FIGS. 1a and 1b are two bi-layer structures with and without an n- or p-modulation doping, respectively, according to the present invention.

FIG. 2 shows a Sb-based conventional single-gate MISFET structure according to the present invention.

FIG. 3 shows a Sb-based self-aligned gate MISFET structure according to the present invention.

FIG. 4 shows a Sb-based self-aligned T-gate MISFET structure according to the present invention.

FIG. 5 shows a Sb-based self-aligned triple-gate MISFET structure according to the present invention.

FIG. 6 shows a Sb-based complementary MISFETs which integrates two self-aligned T-gate MISFETs according to the present invention.

FIG. 7 shows a Sb-based complementary MISFETs structure which integrates two triple-gate MISFETs according to the present invention.

FIG. 8 shows the Sb-based device structure which monolithically integrates a set of complementary MISFETs using two conventional single-gate MISFETs and a set of complementary MISFETs using two triple-gate MISFETs according to the present invention.

FIG. 9 shows the Sb-based device structure which monolithically integrates a set of complementary MISFETs using two conventional single-gate MOSFETs, a set of complementary MISFETs using two triple-gate MISFETs, one triple-gate MISFET, and one conventional single-gate MISFET according to the present invention.

### DETAILED DESCRIPTION

The present invention and embodiments are now described in detail. In the diagrams and descriptions below, the same symbols are utilized to represent the same or similar elements. The possible embodiments of the present invention are described in illustrations. Additionally, all elements of the drawings are not depicted in proportional sizes but in relative sizes.

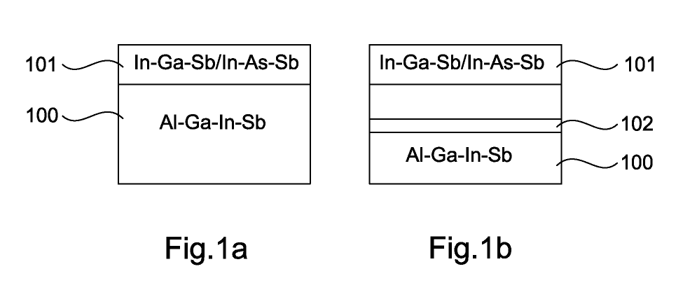

Referring to FIGS. 1a and 1b, they show a Sb-based epitaxial layer structures for an E/D mode MISFET according to the present invention. In FIG. 1a, it shows a bi-layer structure of a E-mode MISFET, wherein the bi-layer structure comprises a first layer 100 which material is the combination of Al(aluminum)-Ga(gallium)-In(indium)-Sb(antimony) as a buffer layer, and a second layer 101 which material is the combination of In—Ga—Sb or In—As(arsenic)-Sb formed on the buffer layer 100 as a channel layer. No n- or p-modulation doping 102 is formed in the buffer layer 100. The layer structure in FIG. 1a is used for an E-mode MISFET. By contrast, an n- or p-modulation doping 102 is formed in the buffer layer 100 and at a specified depth beneath the channel. The depth of the n- or p-modulation doping 102 may be adjusted depending on the requirement in device performance. The layer structure in FIG. 1a is used for a D-mode MISFET. Except for the modulation doping layer, the two layer structures in FIGS. 1a and 1b are identical. Moreover, whichever D-mode or E-mode MISFET is to be made, a channel layer can be made by either InₓGa₁₋ₓSb or InAsₓSb₁₋ₓ, wherein x is equal to 0˜1.0. The two InGaSb or InAsSb channel layers, simultaneously have excellent electron and hole mobilities. The buffer layer can made by AlₓGa_{y}In_{z}Sb, wherein x+y+z is equal to 1.0. Moreover, the bi-layer structure may be formed on a substrate which material comprises Si, InP or GaAs.

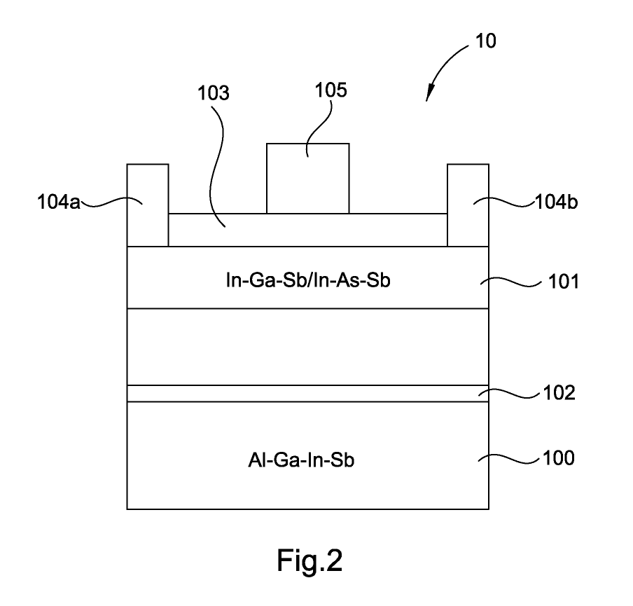

Referring to FIG. 2, it shows a Sb-based D-mode MISFET according to the present invention, wherein an Al-Ga—In—Sb buffer layer 100 is used. An n- or p-modulation doping layer 102 is formed in the buffer layer 100 and at a specified depth beneath the channel, wherein the n-modulation doping layer 102 is used for n-channel D-mode MISFET, the p-modulation doping layer 102 is used for p-channel D-mode MISFET, and no modulation doping layer 102 is used for n- or p-channel E-mode MISFET. An In—Ga—Sb or In—As—Sb channel layer 101 is formed on the buffer layer 100. High-k or SiO₂ dielectric layer 103 is formed on the channel layer 101 as a gate dielectric. A gate 105 is formed on the gate dielectric layer 103. After selective removal of the gate dielectric layer 103, source and drain contacts 104a/104b are formed on the channel layer 101 and at two-sides of the gate 105.

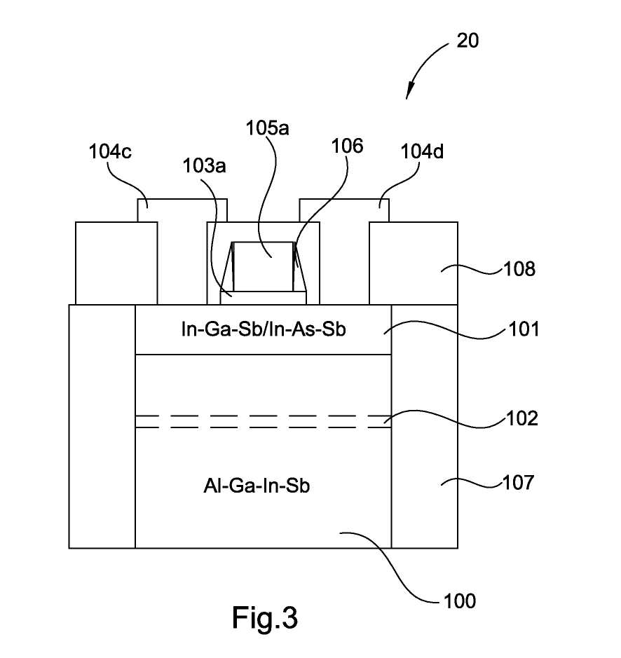

FIG. 3 shows a Sb-based self-aligned MISFET according to the present invention. Epitaxial layer structure in the FIG. 3 is the same as those in the FIG. 1, and relative identical descriptions are therefore omitted. In such a MISFET device, a high-k dielectric layer is selectively formed on the channel layer 101 to be a gate dielectric layer 103a. A gate 105a is formed on the gate dielectric layer 103a and a spacer 106 is formed on the sidewalls of the gate 105a. For example, the gate 105a is a metallic gate and material of the spacer 106 is silicon nitride or silicon oxide. Self-aligned ion implantation wherein the implant ion is chosen for forming a highly-doped channel layer 101 is performed in source/drain regions that are right next to the two-sides of said gate 105a Annealing is implemented to activate the carriers. A shallow trench isolation (STI) layer 107 is formed to electrically isolate the devices, and material of the STI layer 107 may be silicon oxide. A low-k dielectric layer 108 is formed on the channel layer 101, the STI layer 107, and covers the whole gate structure, 105a and 103a. The low-k material layer 108 has vias for depositing source/drain ohmic metals 104c/104d on the channel layer 101. The ohmic metals for the source/drain contacts 104c/104d are the ones for forming good ohmic contacts. To summarize, such a device structure utilizes the metallic gate and the sidewall spacer as a mask to form self-aligned ohmic contacts, thus reducing parasitic capacitance and resistance in device access region.

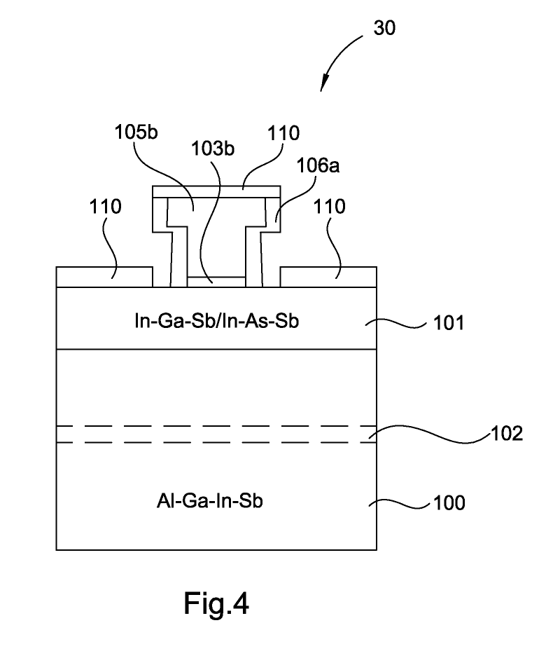

FIG. 4 shows another Sb-based self-aligned MISFET according to the present invention. Epitaxial layer structure in the FIG. 4 is the same as those in the FIG. 1, and relative identical descriptions are therefore omitted. A high-k dielectric layer 103b is formed on the channel layer 101 to be a gate dielectric layer. A T-gate 105b is formed on the gate dielectric layer 103b, and a spacer 106a is formed on a sidewall of the T-gate 105b. After spacers 106a are formed on the sidewalls of the T-gate 105b, self-aligned source and drain metals 110 are formed on the channel layer 101 using the suitable source/drain metals. For example, the metals for the source/drain contacts 110 are the ones for forming good ohmic contacts. To summarize such device structure utilizes the T-shape metal gate structure as a mask to form self-aligned ohmic contacts on two-sides of the gate, thus reducing channel parasitic capacitance and resistance in device access region.

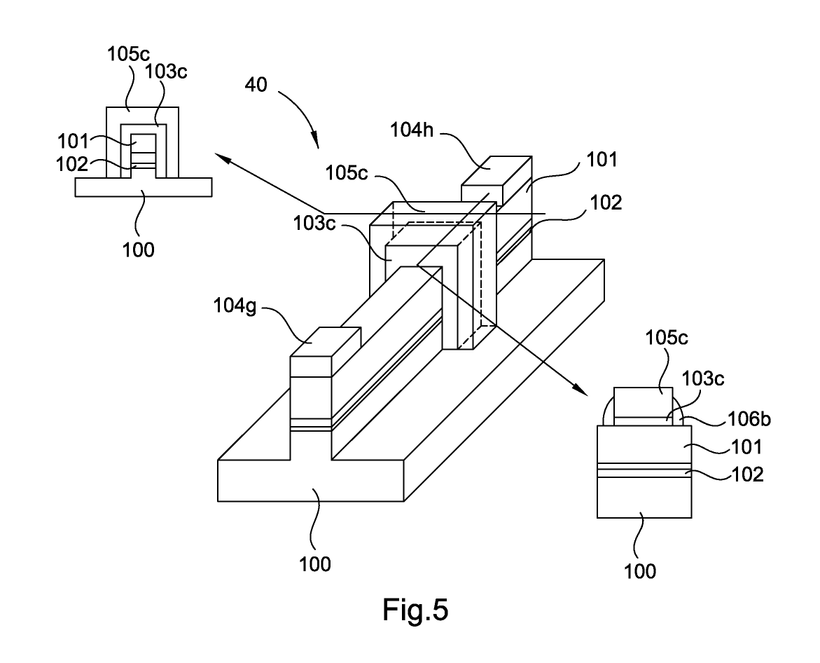

FIG. 5 shows a Sb-based self-aligned triple-gate MISFET according to the present invention. A high-k dielectric layer 103c is deposited on a patterned surface where one-dimensional channel layer 101 is formed as a gate dielectric layer. A gate 105c that spans one-dimensional channel 101 is formed on said gate dielectric layer. An n- or p-modulation doping layer 102 is optionally formed in the buffer layer 100 and at a specified depth beneath the channel, wherein the modulation doping layer 102 can be n-modulation doping for n-channel D-mode MISFET, p-modulation doping for p-channel D-mode MISFET, and no modulation doping for n- or p-channel E-mode MISFET. Spacers 106b are formed on sidewalls of the gate, shown in right side of the FIG. 5 which shows right side cross-sectional view of the MISFET. The left side of the FIG. 5 shows front side cross-sectional view of the MISFET Self-aligned source/drain contacts 104g/104h are formed on two-sides of said gate 105c by using a process of ion implantation, annealing, and ohmic metal deposition. To summarize such device structure utilizes the triple-gate structure to control channel conduction and a self-aligned gate process for reducing channel parasitic capacitance and resistance in device access region.

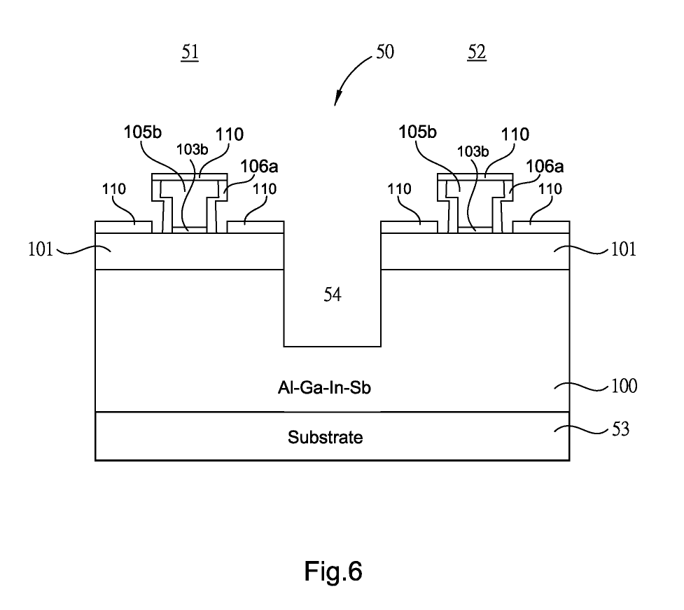

FIG. 6 shows a Sb-based self-aligned T-gate complementary MISFET according to the present invention. The Sb-based complementary MISFETs 50 comprises a self-aligned T-gate n-channel MISFET 51 and a self-aligned T-gate p-channel MISFET 52. In this embodiment, the epitaxial layer structure without modulation doping may be chosen for forming n- and p-channel E-mode MISFETs. The MISFET 51 and 52 have a common channel layer and are formed on the same substrate 53. The MISFET 51 and 52 are isolated each other with a region or opening 54 formed by using either wet or dry etching, for example etching stop at a specified depth below the channel layer. The two T-gate MISFETs in the Sb-based complementary MISFETs 50 may refer to the FIG. 4 and relative detailed descriptions are thus omitted.

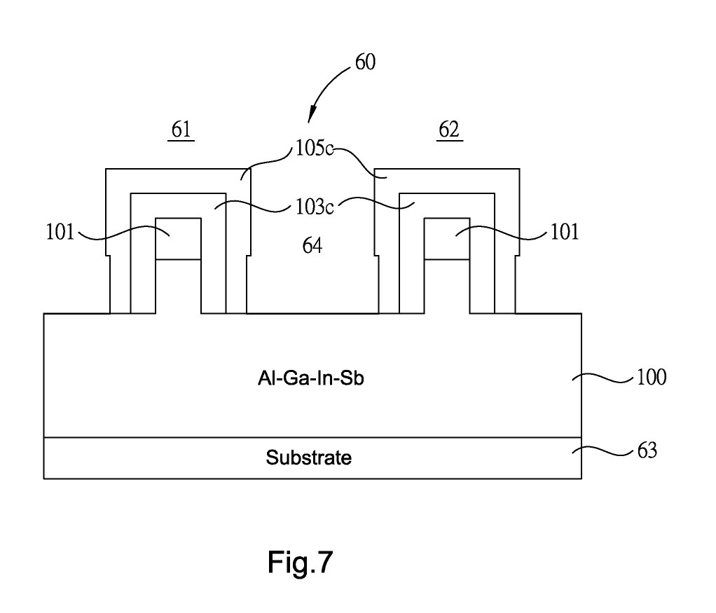

FIG. 7 shows a Sb-based self-aligned triple-gate complementary MISFET according to the present invention. The Sb-based complementary MISFET 60 comprises a self-aligned triple-gate n-channel MISFET 61 and a self-aligned triple-gate p-channel MISFET 62. The MISFET 61 and 62 have a common channel layer and are formed on the same substrate 63. The two MISFETS 61 and 62 are isolated each other with a region 64. The two tri-gate MISFETs in the Sb-based complementary MISFETs 60 may refer to FIG. 5, and relative detailed descriptions are thus omitted.

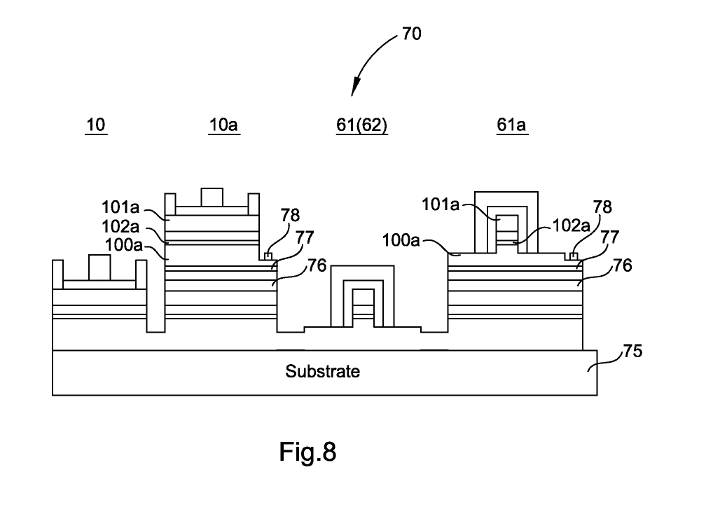

Furthermore, another embodiment of the above invented various devices is two sets of complementary MISFETs monolithically fabricated on the same substrate. Each of the two sets of complementary MISFETs can be formed by any of the invented MISFETs referred to the FIGS. 2, 3, 4, and 5 and relative detailed descriptions are thus omitted. The epitaxial materials for the two sets of complementary MISFETs to be formed are composed of a stacked layer structures that is composed of any of the invented layer structures shown in FIG. 1a and FIG. 1b. The two MISFETs in any of the two sets of complementary MISFETs can be formed either both on the upper layer structure, one on the upper and another on the lower layer structure, or both on the lower layer structure. For the purposes of device development and integration, the epitaxial materials have several following features: the modulation doping layer for each of the two layer structures is optional; the sequence of the upper and lower layer structures in the epitaxial materials is exchangeable; an additional doping layer in the upper layer structure is formed for formation of a back gate in the upper MISFET; an etch stop layer is formed between the upper and lower layer structures. FIG. 8 shows one of many possibilities mentioned above, wherein the monolithically integrated complementary MISFETs 70 comprises two conventional single-gate MISFETs and two triple-gate MISFETs, which include a n-channel D-mode MISFET 10, a p-channel D-mode MISFET 10a, a n-channel triple-gate D-mode MISFET (61(62)) and a p-channel triple-gate D-mode MISFET 61a, wherein the n- and p-channel MISFETs that are used for forming complementary MISFETs do not have a common channel layer but are made on the same substrate. An additional doping layer 77 in the upper layer structure is formed for formation of a back gate 78 in the upper MISFET. An etch stop layer 76 is formed between the upper and lower layer structures. The above-mentioned devices 10, 10a, (61(62)) and 61a are isolated each other such that the each device may be operated independently.

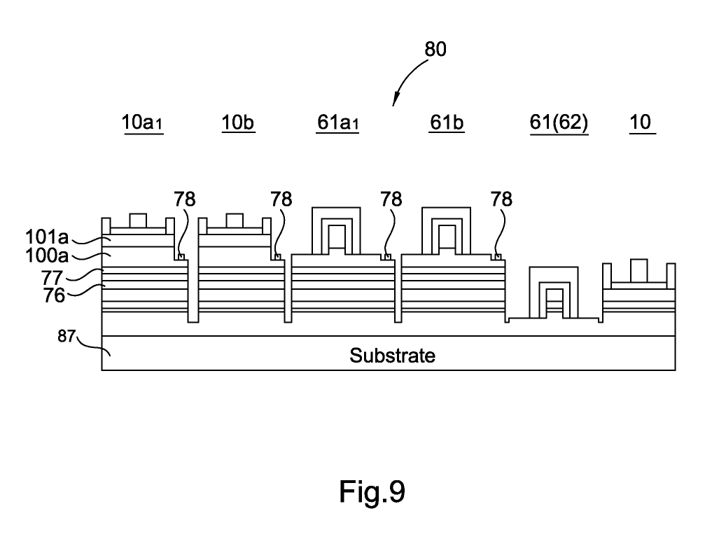

Furthermore, another embodiment of the above invented various devices is a combination of arbitrary numbers of complementary MISFETs and single active MISFETs monolithically fabricated on the same substrate. The additional single active MISFETs are integrated into the embodiment in order to increase the flexibility of circuit applications. The complementary MISFETs and single active MISFETs can be formed by any of the invented MISFETs referred to the FIGS. 2, 3, 4, and 5 and relative detailed descriptions are thus omitted. The epitaxial materials for the two sets of complementary MISFETs to be formed are a stacked layer structures that is composed of any of the invented layer structures shown in FIGS. 1a and b. The two MISFETs in any of the complementary MISFETs can be formed either both on the upper layer structure, or one on the upper and another on the lower layer structure, or both on the lower layer structure. For the purposes of device development and integration, the epitaxial materials have several following features: the modulation doping layer for any of the two layer structures is optional; the sequence of the upper and lower layer structures in the epitaxial materials is exchangeable; an additional doping layer in the upper layer structure is formed for formation of a back gate in the upper MISFET; an etch stop layer is given between the upper and lower layer structures. FIG. 9 shows one of many possibilities mentioned above, wherein the monolithically integrated device structure 80 comprises one set of complementary MISFETs using two conventional single-gate MISFETs (10a1 and 10b), one set of complementary MISFETs using two triple-gate MISFETs (61a1 and 61b), one single triple-gate MISFET (61(62)), and one single conventional single-gate MISFETs (10). An additional doping layer 77 in the upper layer structure is formed for formation of a back gate 78 in the upper MISFET. An etch stop layer 76 is formed between the upper and lower layer structures. The two conventional single-gate (10a1 and 10b) and two triple-gate (61a1 and 61b) MISFETs for complementary MISFETs are both composed of one n-channel E-mode and one p-channel E-mode MISFETs. The single triple-gate (61(62)) and conventional single-gate (10) MISFETs are both n- or p-channel D-mode MISFETs.

What is claimed is:

1. A structure of Sb-based epitaxial layers for fabrication of n/p-channel E/D-mode MISFETs, which comprises:
a buffer layer, which material is a combination of Al(aluminum), Ga(gallium), In(indium) and Sb(antimony), wherein said combination is AlₓGa_{y}In_{z}Sb and x+y+z is equal to 1.0;
a channel layer, which is formed on said buffer layer and which material is a combination of 1n(indium), Ga(gallium) and Sb(antimony) or In(indium), As(arsenic) and Sb(antimony), wherein said combination is InₓGa₁₋ₓSb or InAsₓSb₁₋ₓ, wherein x is between to 0 and 1.0, can both be used for n- and p-channel layers; and
a modulation doping layer, which can be optionally used, formed at a specified depth below said channel layer.

2. A structure of n/p-channel E/D-mode MISFETs, which comprises:
a buffer layer, which material is a combination of Al(aluminum), Ga(gallium), In(indium) and Sb(antimony), wherein said combination is AlₓGa_{y}In_{z}Sb and x+y+z is equal to 1.0;
a channel layer, which is formed on said buffer layer and which material is a combination of 1n(indium), Ga(gallium) and Sb(antimony) or In(indium), As(arsenic) and Sb(antimony), wherein said combination is InₓGa₁₋ₓSb or InAsₓSb₁₋ₓ, wherein x is between to 0 and 1.0, can both be used for n- and p-channel layers; and
a modulation doping layer, which can be optionally used, formed at a specified depth below said channel layer.

3. The structures in claim 2, further comprising:
a high-k dielectric layer formed on said channel layer as a gate dielectric layer;
a gate formed on said gate dielectric layer; and
source and drain contacts formed on said channel layer and two-sides of said gate.

4. The structures in claim 2, further comprising:
a high-k dielectric layer formed on said channel layer as a gate dielectric layer;
a gate formed on said gate dielectric layer;
spacers formed on sidewalls of said gate and on said gate dielectric layer;
a shallow trench isolation (STI) layer formed to isolate said device;
a low-k dielectric layer formed on said channel layer and said STI layer; and
source/drain contacts formed on said channel layer.

5. The structures in claim 2, further comprising:
a high-k dielectric layer formed on said channel layer as a gate dielectric layer;
a T-gate formed on said gate dielectric layer;
spacers formed on sidewalls of said T-gate; and
self-aligned source/drain contacts formed on said channel layer.

6. The structures in claim 2, further comprising:
a high-k dielectric layer formed on a one-dimensional channel structure as a gate dielectric layer;
a gate that spans one-dimensional channel formed on said gate dielectric layer;
spacers are formed on sidewalls of said gate;
self-aligned source/drain contacts formed on said channel layer.

7. A structure of monolithical Sb-based complementary MISFETs according to claim 2, comprising:
a substrate, wherein said channel layer is formed on said substrate and without said modulation doping layer formed below said channel layer; and
wherein said n- and p-channel MISFETs according to claim 4˜6 have a common said channel layer and form on the same said substrate, which are isolated each other.

8. A structure of monolithical Sb-based complementary MISFETs according to claim 2, comprising:
a stacked epitaxial layer structure that has a first epitaxial structure with a first buffer layer and a first channel layer atop of a second epitaxial structure with a second buffer layer and a second channel, wherein materials of said first and second channel layer can be either InAsSb or InGaSb;
an etching stop layer formed between said first epitaxial structure and said second epitaxial structure;
a doped layer inserted in said first buffer layer of said first epitaxial structure to form a back gate;
a first n-channel MISFET formed on said first epitaxial structure and a second p-channel MISFET formed on the said second epitaxial structure;
wherein said first n-channel MISFET and said second p-channel MISFET according to claim 4˜6 do not have a common channel layer and form on the same substrate, which are isolated each other.

9. A structure of monolithically integrating complementary MISFETs and single active MISFETs, comprising:
a stacked epitaxial layer structure that has a first epitaxial structure with a first buffer layer and a first channel layer atop of a second epitaxial structure with a second buffer layer and a second channel, wherein materials of said first and second channel layer can be either InAsSb or InGaSb;
an etching stop layer formed between said first epitaxial structure and said second epitaxial structure;
a doped layer inserted in said first buffer layer of said first epitaxial structure to form a back gate;
at least one set of complementary MISFETs formed on said first epitaxial structure and/or said second epitaxial structure;
at least one single active MISFETs formed on said first epitaxial structure or said second epitaxial structure;
wherein all of said at least one set of complementary MISFETs and said at least one single active MISFETs are integrated on the same substrate, which are isolated each other.
